(19) United States
(12) Patent Application Publication
(10) Pub. No.: US 2009/0080673 A1
(43) Pub. Date: Mar. 26, 2009

(54) SYSTEMS AND METHODS FOR AUTOMATICALLY CONTROLLING THE VOLUME OF A MOTOR VEHICLE ENTERTAINMENT SYSTEM

(75) Inventor: DANIEL P. LAURENT, SALINE, MI (US)

Correspondence Address: INGRASSIA FISHER & LORENZ, P.C. (GM), 7010 E. COCHISE ROAD, SCOTTSDALE, AZ, 85253, US

(73) Assignee: GM GLOBAL TECHNOLOGY OPERATIONS, INC., DETROIT, MI (US)

(21) Appl. No.: 11/860,347

(22) Filed: Sep. 24, 2007

(51) Int. Cl. H03G 3/32; G10K 11/00; H04B 1/00

(52) U.S. Cl. 381/86; 381/108; 381/56; 701/36

(57) ABSTRACT

Systems and methods are provided for controlling the volume of a motor vehicle entertainment system. One motor vehicle includes a sound system, a motor having an idle speed, and a processor. The processor is configured to determine the speed of the motor and to adjust the volume of the sound system if the determined speed is less than or equal to the idle speed. An entertainment system coupleable to a combustion motor includes means for producing sound, means for determining the speed of the combustion motor, and means for adjusting the volume of the sound producing means if the determined speed is less than or equal to a threshold speed. One method includes the steps of determining the speed of the combustion motor and adjusting the volume of the entertainment system if the determined speed is less than or equal to a threshold speed.

### TECHNICAL FIELD

The present invention generally relates to motor vehicles, and more particularly relates to systems and methods for automatically controlling the volume of a motor vehicle entertainment system.

### BACKGROUND OF THE INVENTION

Hybrid motor vehicles typically use a combustion motor to provide torque to the wheels when the hybrid motor vehicle is operating at a rate of vehicle speed or load above related thresholds. Furthermore, hybrid motor vehicles use an electric motor and an electric storage system (e.g., a battery) to provide torque to the wheels or to power on board electrical systems when the hybrid motor vehicle is operating at a rate of speed or a load below the thresholds. Specifically, when the hybrid motor vehicle is slowing down for, or is stopped at, for example, a traffic signal, the combustion motor turns OFF and the electric motor provides the torque needed to restart the combustion motor to increase the speed or propel the hybrid motor vehicle back into motion.

During operation, the combustion motor generates sound that may compete with the sound generated by an entertainment system (e.g., a radio, a CD player, a DVD player, an MP3 player, a navigation system, a communication system, etc.). Often, users of the entertainment system unconsciously take the sound generated by the combustion motor into consideration when setting the volume of the entertainment system. However, when the hybrid motor vehicle is slowing down or is stopped and the combustion motor turns OFF, at times for the entire duration of the stop event, the volume of the entertainment system may seem too high and the user will typically then manually decrease the volume. Similarly, as the hybrid motor vehicle restarts the combustion motor and/or begins operating above the threshold engine speed and the combustion motor turns ON, the volume of the entertainment system may seem too low and the user will typically then manually increase the volume. In the course of a trip, a user may manually decrease/increase the volume of the entertainment system several times as the combustion motor is turned OFF/ON.

Accordingly, it is desirable to provide systems and methods for automatically controlling the volume of a motor vehicle entertainment system. Furthermore, other desirable features and characteristics of the present invention will become apparent from the subsequent detailed description and the appended claims, taken in conjunction with the accompanying drawings and the foregoing technical field and background.

### SUMMARY OF THE INVENTION

Various exemplary embodiments of the invention provide a motor vehicle comprising a sound system having an adjustable volume, a motor having an idle speed, and a processor coupled to the sound system and the motor. The processor is configured to determine the speed of the motor and to adjust the volume of the sound system if the determined speed of the motor is less than or equal to the idle speed.

Other exemplary embodiments of the invention provide entertainment systems coupleable to a combustion motor. One entertainment system comprises means for producing sound, means for determining a speed of the combustion motor, and means for adjusting the volume of the sound producing means if the determined speed is less than or equal to a threshold speed.

Methods for controlling the volume of an entertainment system in a hybrid motor vehicle including a combustion motor are also provided. An exemplary method comprises the steps of determining a speed of the combustion motor and adjusting the volume of the entertainment system if the speed is less than or equal to a threshold speed.

### DESCRIPTION OF THE DRAWINGS

The present invention will hereinafter be described in conjunction with the following drawing figures, wherein like numerals denote like elements, and

FIG. 1 is a schematic diagram of a hybrid motor vehicle comprising an exemplary embodiment of a system for automatically controlling the volume of an entertainment system of the hybrid motor vehicle;

FIG. 2 is a schematic diagram of a motor vehicle comprising another exemplary embodiment of a system for automatically controlling the volume of an entertainment system of the motor vehicle; and

FIG. 3 is a flow diagram of one exemplary embodiment of a method for automatically controlling the volume of a motor vehicle entertainment system.

### DESCRIPTION OF AN EXEMPLARY EMBODIMENT

The following detailed description is merely exemplary in nature and is not intended to limit the invention or the application and uses of the invention. Furthermore, there is no intention to be bound by any expressed or implied theory presented in the preceding technical field, background of the invention, or summary of the invention, or in the following description of an exemplary embodiment.

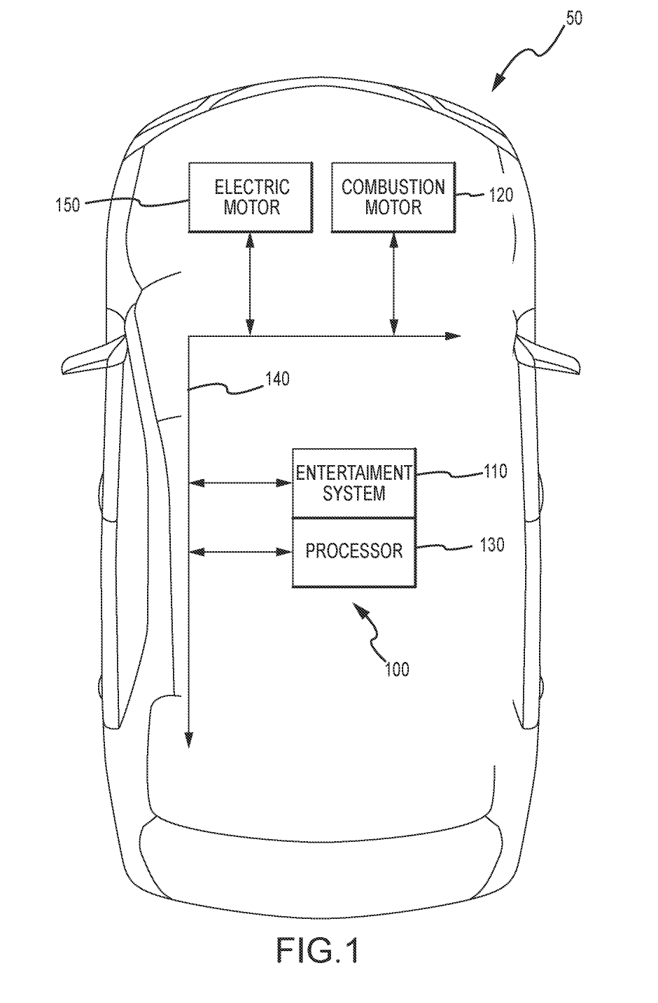

FIG. 1 is a schematic diagram of a hybrid motor vehicle 50 comprising a system 100 for automatically controlling the volume of a motor vehicle entertainment system. System 100 comprises an entertainment system 110, a combustion motor 120, and a processor 130 coupled to one another via a bus 140 (e.g., a wired or wireless bus). Furthermore, being a hybrid motor vehicle, hybrid motor vehicle 50 comprises an electric motor 150 as is known in the art.

Entertainment system 110 may be any hardware and/or device capable of generating sound for entertaining or for providing information to one or more occupants of hybrid motor vehicle 50. Examples of entertainment system 110 include, but are not limited to, a radio, a CD player, a DVD player, an MP3 player, a navigation system, a communication system (e.g., cellular telephone), and the like sound-generating devices and/or sound systems.

Combustion motor 120 may be any combustion motor known in the art or developed in the future. For example, combustion motor 120 may be a motor fueled by gasoline, natural gas, propane, ethanol, hydrogen, and the like combustible substances.

Processor 130 is configured to monitor and determine/detect the speed (e.g., in revolutions-per-minute (RPMs)) of combustion motor 120. Processor 130 is also configured to compare the speed of combustion motor 120 to a threshold speed to determine if combustion motor 120 is operating at a speed greater than, less than, or equal to the threshold speed. In accordance with one exemplary embodiment, the threshold speed is in the range of about 400 RPMs to about 1500 RPMs. In another exemplary embodiment, the threshold speed is the idle speed of hybrid motor vehicle 50, which idle speed may vary as the environmental conditions (e.g., temperature) surrounding hybrid motor vehicle 50 change.

Processor 130 may also be configured to determine if combustion motor 120 is turned OFF or hybrid motor vehicle 50 is being powered by electric motor 150. That is, processor 130 is configured to determine when hybrid motor vehicle 50 is decreasing in speed or is stopped.

In one exemplary embodiment of the invention, processor 130 is configured to decrease the volume of entertainment system 110 if combustion motor 120 is operating at a speed less than or equal to the threshold speed. Processor 130, in another exemplary embodiment, is configured to decrease the volume of entertainment system 110 when processor 130 determines that combustion motor 120 is OFF or detects that hybrid motor vehicle 50 is being powered by electric motor 150.

Processor 130 may be configured to decrease the volume of entertainment system 110 by a pre-determined amount (e.g., an amount in the range of about 0.5 dB to about 3 dB) or to a pre-determined volume. Processor 130 may also be configured to decrease the volume of entertainment system 110 by a pre-determined percentage (e.g., a percentage in the range of about 10% to about 50%). Furthermore, processor 130 may be configured to decrease the volume of entertainment system 110 by a proportional amount depending on the present volume of entertainment system 110. That is, processor 130 decreases the volume of entertainment system 110 a greater amount for higher volumes than for lower volumes. For example, processor 130 may decrease the volume by 10 dB or 90% when entertainment system 110 is at its maximum volume, and may decrease the volume by 1 dB or 20% when entertainment system 110 is operating at less than 50% of the maximum volume.

As used herein, the terms Decibel, decibel levels, and dB, are based on the definition of dB is logarithmic (i.e., dB=10·Log(Power Ratio)). That is, for example, a 3 dB reduction in sound level corresponds to half the power, and a 10 dB reduction to one tenth.

Processor 130 is also configured to increase the volume of entertainment system 110 when processor 130 detects that combustion motor 120 is operating above the threshold speed, is turned ON, or electric motor 150 is not powering hybrid motor vehicle 50. That is, processor 130 is configured to return the volume of entertainment system 110 to the volume entertainment system 110 was producing prior to processor 130 decreasing the volume. To accomplish such, processor 130 includes memory (not shown) to store the volume of entertainment system 110 prior to processor 130 decreasing the volume of entertainment system 110.

Although processor 130 is shown in FIG. 1 as being separate from entertainment system 110, various embodiments of the invention contemplate that processor 130 may be integrated with entertainment system 110. That is, entertainment system 110 may comprise processor 130 or processor 130 may be a stand alone device.

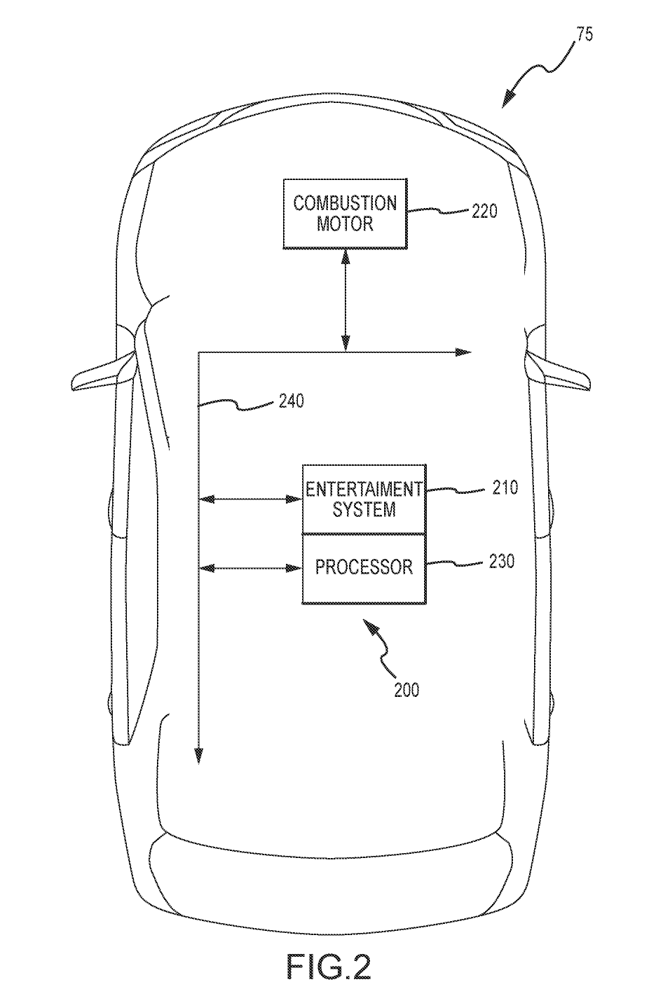

FIG. 2 is a schematic diagram of a motor vehicle 75 comprising another exemplary embodiment of a system 200 for automatically controlling the volume of a motor vehicle entertainment system (e.g., entertainment system 210). System 200 comprises entertainment system 210 and a combustion motor 220 similar to entertainment system 110 and combustion motor 120, respectively, discussed above with reference to FIG. 1. Furthermore, motor vehicle 75 further comprises a processor 230 coupled to entertainment system 210 and combustion motor 220 via a bus 240 (e.g., a wired or wireless bus).

Processor 230 is configured to monitor and determine the speed of combustion motor 220. Processor 230 is also configured to compare the speed of combustion motor 220 to a threshold speed to determine if combustion motor 220 is operating at a speed greater than or equal to the threshold speed.

In accordance with one exemplary embodiment, the threshold speed is in the range of about 600 RPMs to about 1200 RPMs. In another exemplary embodiment, the threshold speed is the idle speed of motor vehicle 75, which idle speed may vary as the environmental conditions (e.g., temperature) surrounding motor vehicle 75 change.

Processor 230 is also configured to decrease the volume of entertainment system 210 if combustion motor 220 is operating at the threshold speed. In one exemplary embodiment, processor 230 is configured to decrease the volume of entertainment system 210 by a pre-determined amount or to a pre-determined volume. Processor 230, in another exemplary embodiment, is configured to decrease the volume of entertainment system 210 by a pre-determined percentage. In yet another embodiment, processor 230 is configured to decrease the volume of entertainment system 210 by a proportional amount depending on the present volume of entertainment system 210 similar to processor 130 (see FIG. 1).

In addition, processor 230 is configured to increase the volume of entertainment system 210 when processor 230 detects that combustion motor 220 is operating at a speed greater than the threshold speed. That is, processor 230 is configured to return the volume of entertainment system 210 to the volume entertainment system 210 was producing prior to processor 230 decreasing the volume. To accomplish such, processor 230 includes memory (not shown) to store the present volume of entertainment system 210 prior to processor 230 decreasing the volume.

Although processor 230 is shown in FIG. 2 as being separate from entertainment system 210, various embodiments of the invention contemplate that processor 230 may be integrated with entertainment system 210. That is, entertainment system 210 may comprise processor 230 or processor 230 may be a stand alone device.

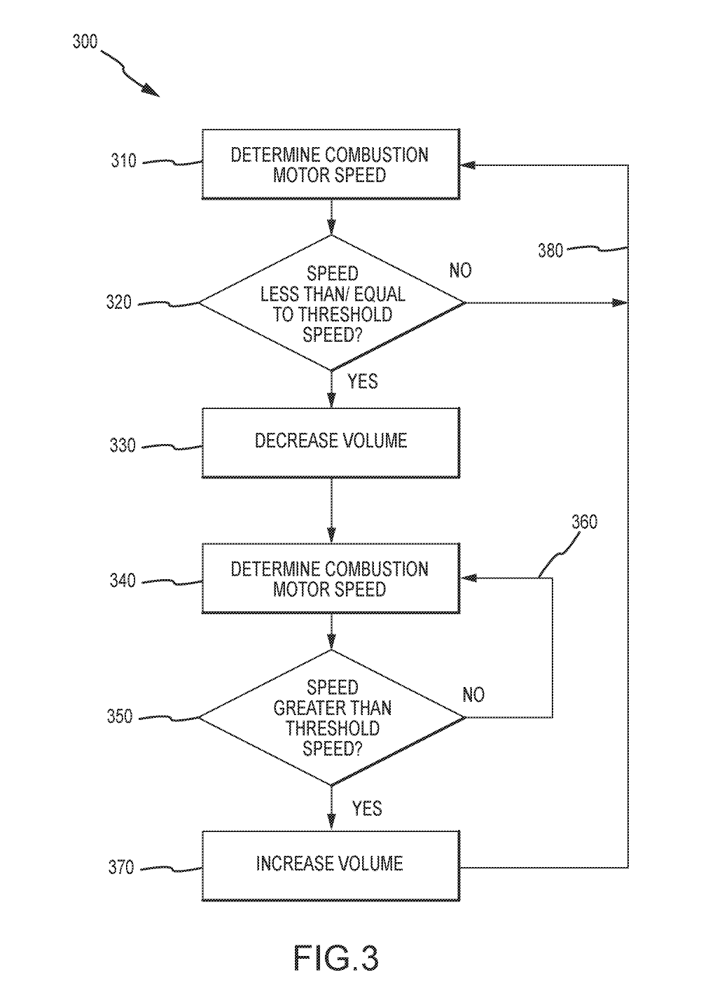

FIG. 3 is a flow diagram of one exemplary embodiment of a method 300 for automatically controlling the volume of an entertainment system (e.g., entertainment systems 110 and 210) of a motor vehicle (e.g., motor vehicles 50 and 75). Method 300 begins by a processor (e.g., processors 130 and 230) determining the speed of a combustion motor (e.g., combustion motors 120 and 220) of the motor vehicle (step 3 10).

The processor then determines if the combustion motor speed is less than or equal to a threshold speed (step 320). In accordance with one exemplary embodiment, the threshold speed is in the range of about 400 RPMs to about 1500 RPMs. The threshold speed, in another exemplary embodiment, is the idle speed of the motor vehicle, which idle speed may vary as the environmental conditions (e.g., temperature) surrounding the motor vehicle change. In yet another exemplary embodiment, the threshold speed is zero RPMS. That is, the processor determines/detects if the combustion motor is ON or if an electric motor (e.g., electric motor 250) of the motor vehicle is responsible for powering the motor vehicle.

If the combustion motor is operating at a speed greater than the threshold speed, the processor continues to monitor the speed of the combustion motor (step 380). If the combustion motor is operating at a speed less than or equal to the threshold speed, the processor decreases the volume of the entertainment system (step 330).

In accordance with one exemplary embodiment, the volume of the entertainment system is decreased by a pre-determined amount. The volume, in another embodiment, is decreased by a pre-determined percentage. In yet another embodiment, the volume is decreased by a proportional amount depending on the present volume of the entertainment system.

When the volume of the entertainment system is decreased, the processor again determines the speed of the combustion motor (step 340). The processor then determines if the combustion motor speed continues to be less than or equal to the threshold speed (step 350).

If the speed continues to be less than or equal to the threshold speed, the processor continues to monitor the speed of the combustion motor (step 360). If the combustion motor is operating at a speed greater than the threshold speed, the processor increases the volume of the entertainment system (step 370). The volume should be increased back to the volume level the entertainment system was producing prior to the processor decreasing the volume; however, other increases in volume are contemplated by various embodiments of the invention.

After the volume is increased, the processor continues to monitor the speed of the combustion motor (step 380). That is, method 300 repeats one or more of steps 310-370 as needed.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

I claim:

1. A motor vehicle, comprising:
a sound system having an adjustable volume;
a motor having an idle speed; and
a processor coupled to the sound system and the motor, the processor configured to determine a speed of the motor and to adjust the volume of the sound system if the determined speed is less than or equal to the idle speed.

2. The motor vehicle of claim 1, wherein the motor vehicle is a hybrid motor vehicle and the processor is configured to decrease the volume if the speed is less than or equal to the idle speed.

3. The motor vehicle of claim 2, wherein the processor is further configured to increase the volume if the speed increases above the idle speed.

4. The motor vehicle of claim 1, wherein the processor is configured to decrease the volume to a pre-determined volume.

5. The motor vehicle of claim 1, wherein the processor is configured to decrease the volume a pre-determined amount.

6. The motor vehicle of claim 1, wherein the processor is configured to decrease the volume a pre-determined percentage.

7. An entertainment system coupleable to a combustion motor, comprising:
means for producing sound;
means for determining a speed of the combustion motor; and
means for adjusting a volume of the sound producing means if the speed is less than or equal to a threshold speed.

8. The entertainment system of claim 7, wherein the adjusting means comprises means for decreasing the volume if the speed is less than or equal to the threshold speed.

9. The entertainment system of claim 8, wherein the adjusting means further comprises means for increasing the volume if the determined speed increases above the threshold speed.

10. The entertainment system of claim 8, wherein the adjusting means further comprises means for decreasing the volume to a pre-determined volume.

11. The entertainment system of claim 8, wherein the adjusting means further comprises means for decreasing the volume a pre-determined amount.

12. The entertainment system of claim 8, wherein the adjusting means further comprises means for decreasing the volume a pre-determined percentage.

13. The entertainment system of claim 8, wherein the threshold speed is an idle speed of the combustion motor.

14. A method for controlling a volume of an entertainment system in a hybrid motor vehicle including a combustion motor, the method comprising the steps of:
determining a speed of the combustion motor; and
adjusting the volume of the entertainment system if the determined speed is less than or equal to a threshold speed.

15. The method of claim 14, wherein the adjusting step comprises the step of decreasing the volume of the entertainment system if the determined speed is less than or equal to the threshold speed.

16. The method of claim 15, further comprising the step of increasing the volume of the entertainment system if the speed increases above the threshold speed.

17. The method of claim 15, wherein the decreasing step comprises the step of decreasing the volume to a pre-determined volume.

18. The method of claim 15, wherein the decreasing step comprises the step of decreasing the volume a pre-determined amount.

19. The method of claim 15, wherein the decreasing step comprises the step of decreasing the volume a pre-determined percentage.

20. The method of claim 14, wherein the threshold speed is an idle speed of the combustion motor.
